(19) United States
(12) Patent Application Publication
(10) Pub. No.: US 2021/0035767 A1
(43) Pub. Date: Feb. 4, 2021

(54) METHODS FOR REPAIRING A RECESS OF A CHAMBER COMPONENT

(71) Applicant: Applied Materials, Inc., Santa Clara, CA (US)

(72) Inventors: Gang Grant PENG, Fremont, CA (US); Wai-Fan YAU, Los Altos, CA (US); David W. GROECHEL, Los Altos Hills, CA (US); Frank F. HOOSHDARAN, Pleasanton, CA (US); Tom K. CHO, Los Altos, CA (US); Yao-Hung YANG, Santa Clara, CA (US)

(21) Appl. No.: 16/525,465

(22) Filed: Jul. 29, 2019

(51) Int. Cl. H01J 9/24; B23K 26/082; B23K 26/12; B23K 26/352

(52) U.S. Cl. CPC H01J 9/245; B23K 26/082; H01L 21/67069; B23K 26/3576; B23K 26/1224

(57) ABSTRACT

Embodiments of the present disclosure generally relate to a method for forming and treating a component in semiconductor manufacturing. In one embodiment, a method for treating a chamber component used in vacuum processing includes obtaining the chamber component including a recess formed in a surface of the chamber component, the surface being fabricated from a metal, and the recess has a depth ranging from about 0.5 mm to about 10 mm and a width ranging from about 1 mm to about 15 mm. The method further includes polishing the bottom surface of the recess using a laser to form a polished bottom surface having an Ra number of 1 micron or less. The laser can achieve high quality surface finishing.

### BACKGROUND

### Field

Embodiments of the present disclosure generally relate to a method for forming and treating a component in semiconductor manufacturing.

### Description of the Related Art

The fabrication of microelectronics or integrated circuit devices typically involves a complicated process sequence requiring hundreds of individual steps performed on semiconductors, dielectric, and conductive substrates. Examples of these processes include oxidation, diffusion, ion implantation, thin film deposition, cleaning, etching and lithography. The processes are typically performed in many vacuum processing chambers having a substrate support for supporting a substrate.

In order to keep the low pressure, such as vacuum condition, during the operation, gaskets, such as O-rings, are utilized. The gasket is typically formed in a recess, such as a groove, formed in a surface of a chamber component, such as a substrate support. The surface roughness of the groove bottom, which is the sealing surface, is critical for the system vacuum. Currently, the sealing surface inside the groove is manually polished. The gaskets may be removed from the chamber component using a hard and sharp tool, which often causes the bottom of the recess to be scratched, leading to reduced O-ring sealing surface quality, and therefore the vacuum quality. The dimensions of the recess, such as a groove, is typically small, such as a width ranging from about 1 mm to about 15 mm and a depth ranging from about 0.5 mm to about 10 mm. It is difficult to machine and polish the bottom surface of the recess due to the small dimensions. Therefore, any damages at the groove sealing surface likely will result in the rejection of the substrate support, which has many high value components integrated within the substrate support.

Thus, there is a need for a method for forming and treating a recess bottom surface of a chamber component.

### SUMMARY

Embodiments of the present disclosure generally relate to a method for forming and treating a component in semiconductor manufacturing. In one embodiment, a method for forming a chamber component used in vacuum processing includes obtaining the chamber component, the chamber component having a recess in a surface of the chamber component, the surface being fabricated from a metal, and the recess has a depth ranging from about 0.5 mm to about 10 mm and a width ranging from about 1 mm to about 15 mm. The method further includes polishing a bottom surface of the recess using a is laser treatment to form a polished bottom surface having an Ra number of 1 micron or less.

In another embodiment, a method for treating a chamber component used in vacuum processing includes obtaining the chamber component, the chamber component having a scratch in a bottom surface of a recess formed in a surface of the chamber component, the surface being fabricated from a metal, and the recess has a depth ranging from about 0.5 mm to about 10 mm and a width ranging from about 1 mm to about 15 mm. The method further includes removing the scratch from the bottom surface of the recess using a laser treatment to form a polished bottom surface having an Ra number of 1 micron or less.

In another embodiment, a method for treating a substrate support used in vacuum processing includes obtaining the substrate support, the substrate support having a scratch in a bottom surface of a groove formed in a surface of the substrate support, the surface being fabricated from a metal, and the groove has a depth ranging from about 0.5 mm to about 10 mm and a width ranging from about 1 mm to about 15 mm. The method further includes removing the scratch from the bottom surface of the groove using a laser treatment to form a polished bottom surface having an Ra number of 1 micron or less.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic cross-sectional side view of a vacuum processing chamber according to one embodiment described herein.

FIGS. 2A and 2B are various views of a chamber component of the vacuum processing chamber according to one embodiment described herein.

FIG. 3 is a schematic cross-sectional side view of a high temperature treatment chamber for treating one or more chamber components of the vacuum processing chamber of FIG. 1, according to one embodiment described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to a method for forming and treating a component in semiconductor manufacturing. In one embodiment, a method for treating a chamber component used in vacuum processing includes obtaining the chamber component including a recess formed in a surface of the chamber component, the surface being fabricated from a metal, and the recess has a depth ranging from about 0.5 mm to about 10 mm and a width ranging from about 1 mm to about 15 mm. The method further includes polishing the bottom surface of the recess using a laser to form a polished bottom surface having an Ra number of 1 micron or less. The laser can achieve high quality surface finishing.

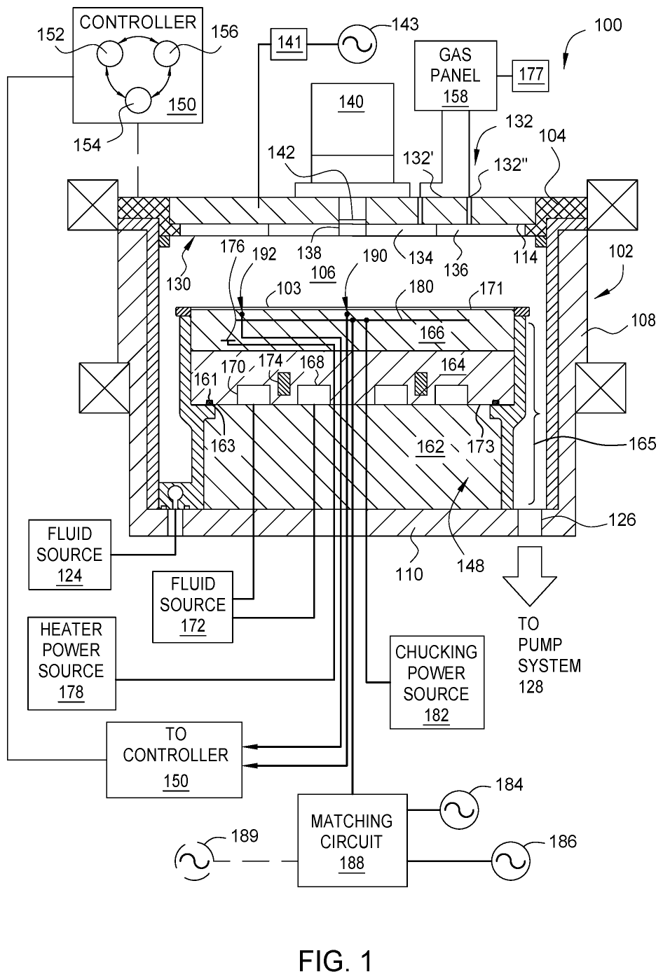

FIG. 1 is a schematic cross-sectional side view of a vacuum processing chamber 100 according to one embodiment described herein. Suitable vacuum processing chambers that may be adapted for use with the teachings disclosed herein include, for example, an ENABLER® or SYM3® vacuum processing chamber available from Applied Materials, Inc. of Santa Clara, Calif. Although the vacuum processing chamber 100 is shown including a plurality of features that enable superior etching performance, it is contemplated that other vacuum processing chambers may be adapted to benefit from one or more of the features disclosed herein.

The vacuum processing chamber 100 includes a chamber body 102 and a lid 104 which enclose an interior volume 106. The chamber body 102 is typically fabricated from aluminum, stainless steel or other suitable material. The chamber body 102 generally includes sidewalls 108 and a bottom 110. A substrate support pedestal access port (not shown) is generally defined in a sidewall 108 and a selectively sealed by a slit valve to facilitate entry and egress of a substrate 103 from the vacuum processing chamber 100. An exhaust port 126 is defined in the chamber body 102 and couples the interior volume 106 to a pump system 128. The pump system 128 generally includes one or more pumps and throttle valves utilized to evacuate and regulate the pressure of the interior volume 106 of the processing chamber 100. In one embodiment, the pump system 128 maintains the pressure inside the interior volume 106 at operating pressures typically between about 10 mTorr to about 500 Torr.

The lid 104 is sealingly supported on the sidewall 108 of the chamber body 102. The lid 104 may be opened to allow excess to the interior volume 106 of the vacuum processing chamber 100. The lid 104 includes a window 142 that facilitates optical process monitoring. In one implementation, the window 142 is comprised of quartz or other suitable material that is transmissive to a signal utilized by an optical monitoring system 140 mounted outside the vacuum processing chamber 100.

The optical monitoring system 140 is positioned to view at least one of the interior volume 106 of the chamber body 102 and/or the substrate 103 positioned on a substrate support pedestal assembly 148 through the window 142. One optical monitoring system that may be adapted to benefit from the disclosure is the EyeD® full-spectrum, interferometric metrology module, available from Applied Materials, Inc., of Santa Clara, Calif.

A gas panel 158 is coupled to the vacuum processing chamber 100 to provide process and/or cleaning gases to the interior volume 106. In the example depicted in FIG. 1, inlet ports 132′, 132″ are provided in the lid 104 to allow gases to be delivered from the gas panel 158 to the interior volume 106 of the vacuum processing chamber 100. In one embodiment, the gas panel 158 is adapted to provide fluorinated process gas through the inlet ports 132′, 132″ and into the interior volume 106 of the vacuum processing chamber 100. A remote plasma source 177 may be optionally coupled to the gas panel 158 to facilitate dissociating gas mixture from a remote plasma prior to entering into the interior volume 106 for processing. An RF source power 143 is coupled through a matching network 141 to a showerhead assembly 130. The RF source power 143 typically is capable of producing up to about 3000 W at a tunable frequency in a range from about 50 kHz to about 100 MHz.

The showerhead assembly 130 is coupled to an interior surface 114 of the lid 104. The showerhead assembly 130 includes a plurality of apertures that allow the gases flowing through the showerhead assembly 130 from the inlet ports 132′, 132″ into the interior volume 106 of the vacuum processing chamber 100 in a predefined distribution across the surface of the substrate 103 being processed in the vacuum processing chamber 100. The showerhead assembly 130 additionally includes a region transmissive to an optical metrology signal. The optically transmissive region or passage 138 is suitable for allowing the optical monitoring system 140 to view the interior volume 106 and/or the substrate 103 positioned on the substrate support pedestal assembly 148.

The substrate support pedestal assembly 148 is disposed in the interior volume 106 of the vacuum processing chamber 100 below the showerhead assembly 130. The substrate support pedestal assembly 148 holds the substrate 103 during processing. The substrate support pedestal assembly 148 generally includes a plurality of lift pins (not shown) disposed therethrough that are configured to lift the substrate 103 from the substrate support pedestal assembly 148 and facilitate exchange of the substrate 103 with a robot (not shown) in a conventional manner.

In one embodiment, the substrate support pedestal assembly 148 includes a mounting plate 162, a base 164 and a substrate support 166. The mounting plate 162 is coupled to the bottom 110 of the chamber body 102 includes passages for routing utilities, such as fluids, power lines and sensor leads, among others, to the base 164 and the substrate support 166. The substrate support 166 may be an electrostatic chuck including at least one clamping electrode 180 for retaining the substrate 103 below showerhead assembly 130. The substrate support 166 is driven by a chucking power source 182 to develop an electrostatic force that holds the substrate 103 to the chuck surface, as is conventionally known. Alternatively, the substrate 103 may be retained to the substrate support pedestal assembly 148 by clamping, vacuum or gravity.

At least one of the base 164 or substrate support 166 may include at least one optional embedded heater 176, at least one optional embedded isolator 174 and a plurality of conduits 168, 170 to control the lateral temperature profile of the substrate support pedestal assembly 148. The conduits 168, 170 are fluidly coupled to a fluid source 172 that circulates a temperature regulating fluid therethrough. The heater 176 is regulated by a power source 178. The conduits 168, 170 and heater 176 are utilized to control the temperature of the base 164, thereby heating and/or cooling the substrate support 166 and ultimately, the temperature profile of the substrate 103 disposed thereon. The temperature of the substrate support 166 and the base 164 may be monitored using a plurality of temperature sensors 190, 192. The substrate support 166 may further comprise a plurality of gas passages (not shown), such as grooves, that are formed in a substrate support pedestal supporting surface of the substrate support 166 and fluidly coupled to a source of a heat transfer (or backside) gas, such as helium. In some embodiments, the base 164 and the substrate support 166 are bonded and are together referred to as the substrate support 165. The substrate support 165 includes a first surface 171 for supporting the substrate 103 and a second surface 173 opposite the first surface 171. The second surface 173 may be in contact with the mounting plate 162. The second surface 173 may be fabricated from a metal, such as aluminum, stainless steel, other suitable metal. A recess 161 is formed in the second surface 173 of the substrate support 165. The recess 161 may be a groove. A gasket 163 is disposed in the recess 161 for maintaining the pressure within the interior volume 106. The gasket 163 may be an O-ring.

In one embodiment, the substrate support pedestal assembly 148 is configured as a cathode and includes an electrode 180 that is coupled to a plurality of RF power bias power sources 184, 186. The RF bias power sources 184, 186 are coupled between the electrode 180 disposed in the substrate support pedestal assembly 148 and another electrode, such as the showerhead assembly 130 or ceiling (lid 104) of the chamber body 102. The RF bias power excites and sustains a plasma discharge formed from the gases disposed in the interior volume 106 of the chamber body 102.

A controller 150 is coupled to the vacuum processing chamber 100 to control operation of the vacuum processing chamber 100. The controller 150 includes a central processing unit (CPU) 152, a memory 154, and a support circuit 156 utilized to control the process sequence and regulate the gas flows from the gas panel 158. The CPU 152 may be any form of general purpose computer processor that may be used in an industrial setting. The software routines can be stored in the memory 154, such as random access memory, read only memory, floppy, or hard disk drive, or other form of digital storage. The support circuit 156 is conventionally coupled to the CPU 152 and may include cache, clock circuits, input/output systems, power supplies, and the like. Bi-directional communications between the controller 150 and the various components of the vacuum processing chamber 100 are handled through numerous signal cables.

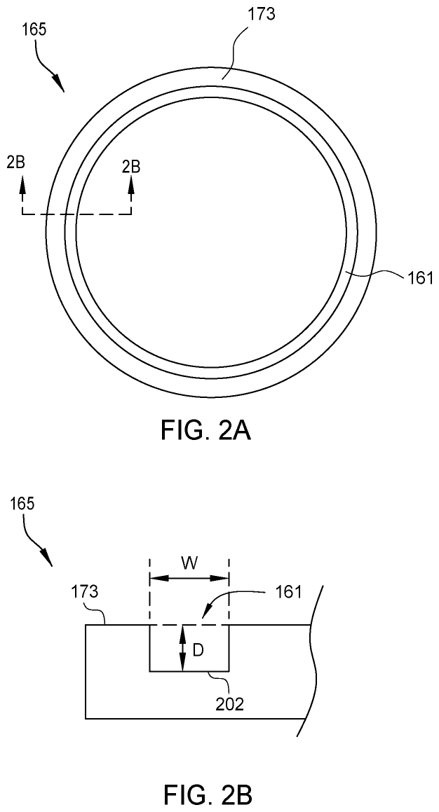

FIGS. 2A and 2B are various views of a chamber component, such as the substrate support 165 of the vacuum processing chamber 100 according to one embodiment described herein. As shown in FIG. 2A, the substrate support 165 includes the surface 173, and the recess 161 is formed in the surface 173. FIG. 2B is an enlarged cross-sectional view of a portion of the substrate support 165 at line 2B-2B shown in FIG. 2A. As shown in FIG. 2B, the recess 161 formed in the surface 173 includes a width W and a depth D. The recess 161 may be referred to as O-ring groove. The width W ranges from about 1 mm to about 15 mm and the depth D ranges from about 0.5 mm to about 10 mm. The gasket 163 (shown in FIG. 1) is disposed in the recess 161. A sharp tool may be used to remove the gasket 163 from the recess 161, and as a result, the bottom surface 202 of the recess 161 is scratched by the sharp tool. In order to remove the scratches formed on the bottom surface 202 of the recess 161, a high temperature treatment (HTT), such as a laser treatment, is performed in the recess 161.

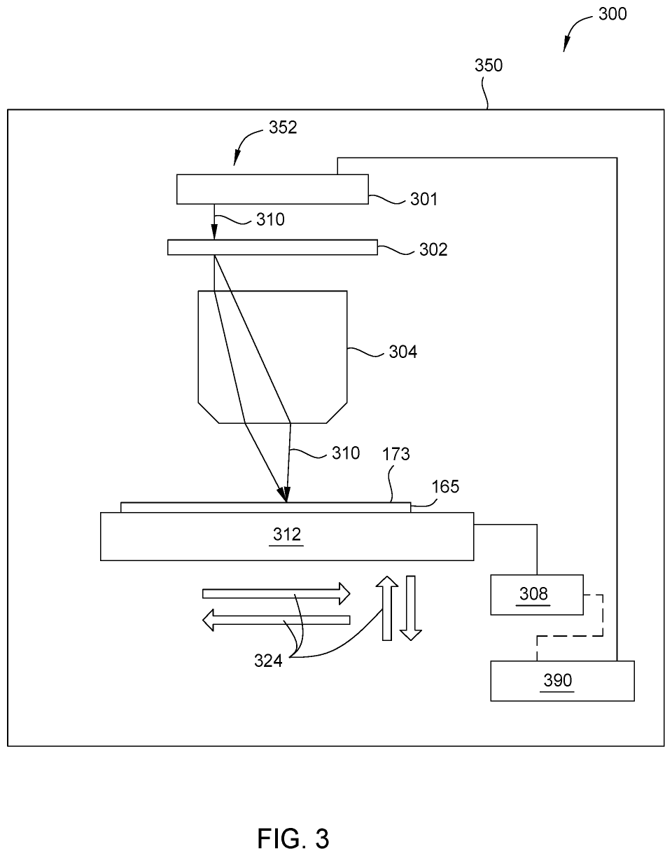

FIG. 3 is a schematic cross-sectional side view of a treatment chamber 300 for treating one or more chamber components of the vacuum processing chamber 100 of FIG. 1, according to one embodiment described herein. The treatment chamber 300 may be utilized to perform a HTT via laser ablation on a chamber component of the vacuum processing chamber 100. For example, the HTT may be a laser treatment, such as laser ablation of the bottom surface 202 of the recess 161 (shown in FIG. 2B). The treatment chamber 300 may be a laser energy apparatus that directs laser energy to the recess 161 formed in the surface 173. Alternatively, the treatment chamber 300 may be any suitable energy providing apparatus that may provide thermal energy, beam energy, light energy, or other suitable energy to polish the bottom surface 202 or to remove scratches from the bottom surface 202 of the recess 161.

The treatment chamber 300 has an enclosure 350 having a laser module 352, a stage 312 configured to support a chamber component, such as the substrate support 165 (shown in FIG. 1), a translation mechanism 324 configured to control the movement of the stage 312. In some embodiments, the chamber component may be a chamber body, a showerhead, or other suitable component that has a surface with a recess formed therein. The chamber component may be obtained and placed on the stage 312. An actuator system 308 may also be coupled to the stage 312 to assist control and movement of the stage 312.

The laser module 352 comprises a laser radiation source 301, at least one lens 302 and an optical focusing and scanning module 304 disposed above the stage 312. In one embodiment, the laser radiation source 301 may be a light source made from Nd:YAG, Nd:YVO₄, crystalline disk, diode pumped fiber and other light source that can provide and emit a pulsed or continuous wave of radiation at a wavelength between about 187 nm and about 10,000 nm, such as between about 248 nm and 2,100 nm. In another embodiment, the laser radiation source 301 may include multiple laser diodes, each of which produce uniform and spatially coherent light at the same wavelength. The power of the laser radiation source 301 ranges from about 0.4 Watts to about 400 Watts.

In one embodiment, the laser radiation source 301 is an IR laser that can emit a pulsed or continuous wave of radiation at a wavelength between about 1060 nm and about 1080 nm. In one embodiment, the laser radiation source 301 is a laser source having a pulse duration from about 10 femtoseconds to about 100 nanoseconds. The laser radiation source 301 may have a repetition rate ranging from about 1 KHz to about 10 MHz, such as from about 10 KHz to about 5 MHz. The laser radiation source 301 may have a scan rate ranging from about 0.01 meters per second to about 30 meters per second.

The optical focusing and scanning module 304 transforms the radiation emitted by the laser radiation source 301 using at least one lens 302 into a line, spot, or other suitable beam configuration, of radiation 310 directed to the bottom surface 202 within the recess 161 in the surface 173 to remove the scratches formed on the bottom surface 202 (shown in FIG. 2B). The size of the beamspot of the laser radiation source 301 is small enough to reach the bottom surface 202 of the recess 161 (shown in FIG. 2B) having very small dimensions. The radiation 310 removes the materials, the scratches or damages, leading to a smooth bottom surface 202. In one embodiment, the bottom surface 202 has a Ra number of 1 micron or less, such as 0.4 micron or less, after being treated by the radiation 310.

Lens 302 may be any suitable lens, or series of lenses, capable of focusing radiation into a line or spot. In one embodiment, lens 302 is a cylindrical lens. Alternatively, lens 302 may be one or more concave lenses, convex lenses, plane mirrors, concave mirrors, convex mirrors, refractive lenses, diffractive lenses, Fresnel lenses, gradient index lenses, or the like.

A controller 390 may be coupled to the actuator system 308 and the laser module 352. The controller 390 may be a high speed computer configured to control the laser module 352 to perform a HTT via laser ablation.

The HTT performed in the treatment chamber 300 may be used to remove scratches or damages on the bottom surface 202 of the recess 161 in the surface 173 of the substrate support 165 (shown in FIG. 2B). In another embodiment, the HTT may be performed to form the substrate support 165. Referring back to FIGS. 2A and 2B, the recess 161 may be formed in the surface 173 by machining, such as milling, other types of mechanical surface finishing, or combinations thereof. The bottom surface 202 of the recess 161 may be rough as the result of the machining process. The HTT may be utilized to polish the bottom surface 202 of the recess 161. The HTT may be laser ablation of the bottom surface 202, which is to expose the bottom surface 202 to a laser radiation. By exposing the bottom surface 202 to the radiation, such as the radiation 310 shown in FIG. 3, the smoothness of the bottom surface 202 of the recess 161 is improved. In one embodiment, the bottom surface 202 has a Ra number of 1 micron or less after being treated by the radiation. The radiation for treating the bottom surface 202 after the formation of the recess 161 may have less power than the radiation 310 used for removing scratches on the bottom surface 202. In one embodiment, the power of the radiation for treating the bottom surface 202 ranges from about 0.4 Watt to about 400 Watt.

Laser based HTT is performed on a bottom surface of a recess having small dimensions. The size of the beamspot produced by the laser is small enough to reach the bottom surface of the recess. Scratches formed on the bottom surface may be removed by the laser based HTT. Furthermore, the laser based HTT may be utilized to form a smooth bottom surface after forming the recess by machining the surface of the chamber component prior to the chamber component being used in operation.

While the foregoing is directed to embodiments of the present disclosure, other and further embodiments of the disclosure may be devised without departing from the basic scope thereof, and the scope thereof is determined by the claims that follow.

What is claimed is:

1. A method for forming a chamber component used in vacuum processing, comprising:
obtaining the chamber component, the chamber component having a recess in a surface of the chamber component, the surface being fabricated from a metal, the recess having a depth ranging from about 0.5 mm to about 10 mm and a width ranging from about 1 mm to about 15 mm; and
polishing a bottom surface of the recess using a laser treatment to form a polished bottom surface having an Ra number of 1 micron or less.

2. The method of claim 1, wherein the chamber component is a substrate support.

3. The method of claim 2, wherein the recess is a groove.

4. The method of claim 3, wherein the laser treatment is laser ablation comprising exposing the bottom surface of the recess to a laser radiation.

5. The method of claim 4, wherein the laser radiation has a power ranging from about 0.4 Watts to about 400 Watts.

6. The method of claim 1, wherein the surface is fabricated from aluminum or stainless steel. The method of claim 1, wherein the recess is formed by milling.

8. A method for treating a chamber component used in vacuum processing, comprising:
obtaining the chamber component, the chamber component having a scratch in a bottom surface of a recess formed in a surface of the chamber component, the surface being fabricated from a metal, the recess having a depth ranging from about 0.5 mm to about 10 mm and a width ranging from about 1 mm to about 15 mm; and
removing the scratch from the bottom surface of the recess using a laser treatment to form a polished bottom surface having an Ra number of 1 micron or less.

9. The method of claim 8, wherein the chamber component is a substrate support.

10. The method of claim 9, wherein the recess is a groove.

11. The method of claim 10, wherein the laser treatment is laser ablation comprising exposing the bottom surface of the recess to a laser radiation.

12. The method of claim 11, wherein the laser radiation has a power ranging from about 0.4 Watt to about 400 Watts.

13. The method of claim 12, wherein the laser radiation has a pulse duration ranging from about 10 femtoseconds to about 100 nanoseconds.

14. The method of claim 13, wherein the laser radiation has a repetition rate ranging from about 1 KHz to about 10 MHz.

15. The method of claim 14, wherein the laser radiation has a scan rate ranging from about 0.01 meters per second to about 30 meters per second.

16. A method for treating a substrate support used in vacuum processing, comprising:
obtaining the substrate support, the substrate support having a scratch in a bottom surface of a groove formed in a surface of the substrate support, the surface being fabricated from a metal, the groove having a depth ranging from about 0.5 mm to about 10 mm and a width ranging from about 1 mm to about 15 mm; and
removing the scratch from the bottom surface of the groove using a laser treatment to form a polished bottom surface having an Ra number of 1 micron or less.

17. The method of claim 16, wherein the laser treatment comprises directing laser radiation to the bottom surface of the groove, wherein the laser radiation has a power ranging from about 0.4 Watt to about 400 Watts.

18. The method of claim 17, wherein the laser radiation has a pulse duration ranging from about 10 femtoseconds to about 100 nanoseconds.

19. The method of claim 18, wherein the laser radiation has a repetition rate ranging from about 1 KHz to about 10 MHz.

20. The method of claim 19, wherein the laser radiation has a scan rate ranging from about 0.01 meters per second to about 30 meters per second.
